(19) United States
(12) Patent Application Publication
(10) Pub. No.: US 2015/0188025 A1
(43) Pub. Date: Jul. 2, 2015

(54) CONTAINER FOR ELECTRONIC COMPONENT AND ELECTRONIC COMPONENT

(71) Applicant: NIHON DEMPA KOGYO CO., LTD., Tokyo (JP)

(72) Inventors: HIROMI OTAKE, SAITAMA (JP); SHARIMAN BIN ABDUL RAHMAN, SAITAMA (JP)

(21) Appl. No.: 14/583,191

(22) Filed: Dec. 25, 2014

(30) Foreign Application Priority Data
Dec. 30, 2013 (CN) 201310743762.6
Mar. 13, 2014 (JP) 2014-050471

(51) Int. Cl. H01L 41/053; B65D 43/06

(52) U.S. Cl. CPC H01L 41/053; B65D 43/06

(57) ABSTRACT

A container for electronic component includes a base and a cover. The base has a side surface and an upper surface. A depressed castellation in plan view is disposed on the side surface. The cover seals the upper surface airtight. The cover has an outside dimension smaller than an outside dimension of the base. The cover has a notch with a radial dimension larger than a depressed radial dimension of the castellation.

### CROSS REFERENCE TO RELATED APPLICATIONS

This application claims the priority benefit of Chinese application serial no. 201310743762.6, filed on Dec. 30, 2013 and Japan application serial no. 2014-050471, filed on March 13, 2014. The entirety of each of the above-mentioned patent applications is hereby incorporated by reference herein and made a part of specification.

### TECHNICAL FIELD

This disclosure relates to a container that includes an airtight sealing cover of a package for glass sealing of an electronic component, for example, a crystal unit, and this disclosure relates to an electronic component.

### DESCRIPTION OF THE RELATED ART

As illustrated in FIG. 7 and FIG. 8, which are perspective views of a package 1, the package 1 for glass sealing of an electronic component, for example, a conventional crystal unit is provided with end face electrodes and depressed castellations (notches) 5 in plan view at four corners of a base 2 made of a ceramic substrate. The end face electrodes are provided on the rear surface of the base 2. The castellations 5 are used for arranging wiring that electrically connects the end face electrodes and internal electrodes of the crystal unit. On the other hand, a cover 3, which is glass sealed and covers an opening of a cavity (space) for mounting a crystal element and a similar member formed on the principal surface of the base 2, includes four corners formed in a rounded R shape so as not to cover the castellations 5 on the base 2 from above.

In order to position and glass-seal the cover 3 on the package 1 with molten glass, the cover 3 is first placed on a recess 10a with a slightly larger outside dimension than that of the cover 3. The recess 10a is formed on a tool 10 placed on a surface plate 10c using the exclusive tool 10 as illustrated in FIG. 9A. Low melting point glass 10d made of a powder compact containing lead is placed on the upper surface of the cover 3. The base 2 is placed on a recess 10b with a slightly larger outside dimension than that of the base 2. The recess 10b is formed on the tool 10 while directing the cavity downward. While heating to around 320° C., as illustrated in FIG. 9B, which is a partial enlarged view of an arrow A of FIG. 9A, the low melting point glass 10d is interposed and bonded between the lower surface of the cover 3 and the upper surface of the base 2. While forming a fillet “f” at the intersection of the side surface of the cover 3 and the upper surface of the base 2, the cover 3 is sealed with glass at the opening of the base 2 so as to seal airtightness of the base 2 (see Japanese Unexamined Patent Application Publication Nos. 2008-271093, 2012-169961, and 2003-133454).

However, there are the following problems. Even when the cover 3 is positioned on the base 2 using the tool 10 described above, due to a minor clearance between the recesses 10a and 10b formed on the tool 10 and the outside profiles of the cover 3 and the base 2, displacement may occur in vertical direction, horizontal direction, or oblique direction in plan view between them. As a result, as illustrated in FIG. 10, the cover 3 should be originally placed at a prescribed position to seal with glass, but as illustrated in FIG. 11, R parts that are formed at four corners of the cover 3 may protrude to the castellations 5.

Recently, as the size and the height of the electronic component such as the crystal unit are increasingly reduced, the soldering state is often automatically inspected using an X-ray image inspection device after mounting the crystal unit on the set substrate.

The automatic inspection of the soldering state using the X-ray image inspection device is generally performed by irradiating the X-ray from above the mounted crystal unit. However, if the displacement of the cover with respect to the base occurs in the image inspection, a defect that solder creeps up from the castellation cannot be visually recognized using the X-ray image inspection device. As a result, there is a problem that the image of a soldering portion cannot be correctly inspected.

A need thus exists for a container for electronic component and an electronic component which are not susceptible to the drawback mentioned above.

### SUMMARY

A container for electronic component according to this disclosure includes a base and a cover. The base has a side surface and an upper surface. A depressed castellation in plan view is disposed on the side surface. The cover seals the upper surface airtight. The cover has an outside dimension smaller than an outside dimension of the base. The cover has a notch with a radial dimension larger than a depressed radial dimension of the castellation.

### BRIEF DESCRIPTION OF THE DRAWINGS

The foregoing and additional features and characteristics of this disclosure will become more apparent from the following detailed description considered with reference to the accompanying drawings.

FIG. 1A is a front view illustrating a crystal unit using a container for electronic component according to this disclosure.

FIG. 1B is a plan view illustrating the crystal unit using the container for electronic component according to this disclosure.

FIG. 2 is a plan view illustrating a base and a cover wherein the base has castellations at four corners of the crystal unit illustrated in FIG. 1A and FIG. 1B, the cover has depressed notches in plan view at four corners, the depressed notches have a larger radial dimension than that of the castellations, and a displacement occurs downward and rightward in plan view between the base and the cover.

FIG. 3 is a plan view illustrating the base and the cover of the crystal unit illustrated in FIG. 1A and FIG. 1B wherein the cover has a chamfered surfaces at four corners, the chamfered surfaces have a larger radial dimension than that of the castellations in a radial direction, and a displacement occurs downward and rightward in plan view between the cover and the base.

FIG. 4 is a cross-sectional view taken along the line IV-IV of FIG. 1B.

FIG. 5 is a partial plan view illustrating a container for electronic component according to an embodiment of this disclosure wherein the base has the castellation on the long side surface of the base, the cover has the notches corresponding to the base, the notches have a radial dimension larger than a radial dimension of the castellation.

FIG. 6A, FIG. 6B, FIG. 6C, FIG. 6D, and FIG. 6E are partial plan views illustrating respective shapes of castellations on the base of the crystal unit and methods for forming according to other embodiments.

FIG. 7 is a perspective view illustrating a conventional crystal unit from above the cover.

FIG. 8 is a perspective view illustrating the crystal unit illustrated in FIG. 7 from the bottom surface direction of the base.

FIG. 9A and FIG. 9B are sectional views illustrating a tool to position and glass-seal the cover on the conventionally used base.

FIG. 10 is a plan view illustrating a state where a displacement doesn't occur between the cover and the base of the conventional crystal unit.

FIG. 11 is a plan view illustrating a state where a displacement occurs downward and rightward between the cover illustrated in FIG. 10 and the base, and the castellations are covered with the four corners of the cover.

### DETAILED DESCRIPTION

A description will hereinafter be made on an embodiment of the container for the electronic component of this disclosure with reference to the accompanying drawings.

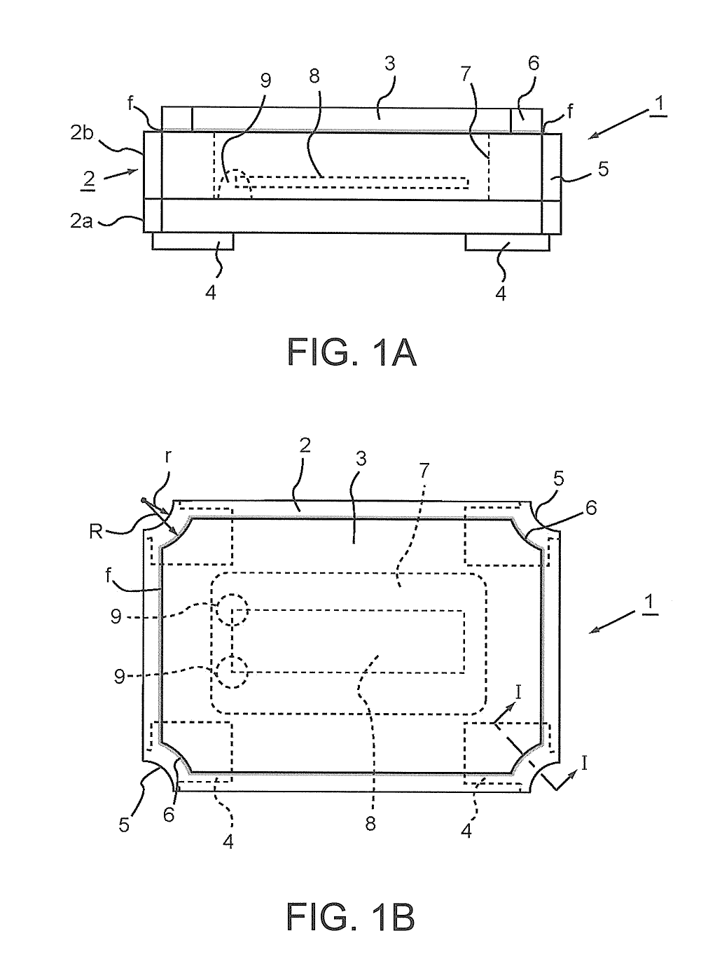

As illustrated in FIG. 1A and FIG. 1B, the electronic component, for example, a crystal unit 1 as one type of the piezoelectric device includes a ceramic base 2 made of ceramic substrates 2a and 2b, a ceramic substrate, and a cover 3. The ceramic substrate is placed on the ceramic base 2, contains lead, and seals airtightness with a fillet “f” of low melting point glass whose melting point is around 320° C. The cover 3 has a smaller outside dimension than that of the ceramic base 2. A quartz crystal vibrating piece 8 is bonded and maintained on the inner bottom surface of a cavity (space portion) 7 that is formed on the ceramic base 2 by conductive adhesives 9. Here, a container (package) in this disclosure is obtained by combining the ceramic base 2 and the cover 3.

Here, since the cover 3 is formed to have a smaller outside dimension than that of the ceramic base 2, when the low melting point glass is hardened over the side surface of the cover 3 and the upper surface of the ceramic base 2, the fillet “f” is formed. As a result, strength at a sealing portion is sufficiently maintained by the cover 3.

In addition, end face electrodes (mounting terminals) 4 are formed at four corners of the outer bottom surface of the ceramic base 2. Here, the number of the mounting terminals 4 is set to be four, but this disclosure can be applied to a piezoelectric device that has two terminals or six terminals, for example, a crystal unit and a crystal oscillator.

Also, castellations 5 that have a quarter circle shape in plan view are formed at respective four corners of the ceramic base 2, and a wiring that electrically connects the end face electrodes 4 and internal electrodes is arranged.

Here, in this embodiment, one space portion is formed on the ceramic base 2, and only the crystal element is mounted on the ceramic base 2. However, a crystal oscillator may be configured as follows. A ceramic base with an H-shaped section is used, and the crystal element is mounted on one space portion, and an IC chip or a similar member is mounted on the other space portion 7.

In addition, in this embodiment, the cover 3 is made of the ceramic substrate. However, instead of the ceramic substrate, Kovar that is prepared by blending iron with nickel and cobalt may be used, and a silver solder alloy (Ag+Cu), a gold-tin alloy (Au+Sn), or a similar material may be used for sealing.

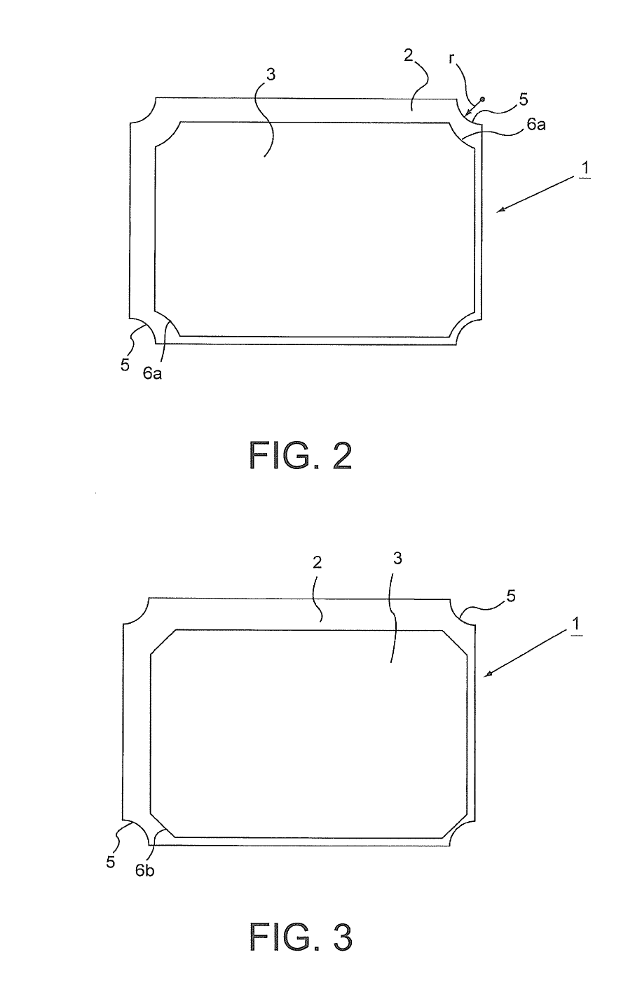

In the embodiment of this disclosure, as illustrated in plan view of FIG. 2, the cover 3 has a smaller outside dimension than an outside dimension of the ceramic base 2. The cover 3 has notches 6a with a radius “R” at four corners of the cover 3. The radius “R” is equal to or same as a radius “r” of a quarter circle shape in plan view of the castellation 5 formed at four corners of the ceramic base 2. As a result, even if the displacement of the cover 3 with respect to the ceramic base 2 occurs in vertical direction, horizontal direction or oblique direction in plan view during sealing, the radius “R” of the notches 6a is formed to be larger than the radial dimension of the castellations 5. Therefore, since R parts (rounded parts) that are formed at four corners of the cover 3 don't protrude to the castellations 5, this avoid the risk that the castellations 5 are covered with the R parts.

In addition, in another embodiment of this disclosure, as illustrated in FIG. 3, C surfaces (chamfers) 6b, which are cut at an angle of 45°, are formed at the four corners of the cover 3 such that dimensions from respective apexes at the four corners become larger than the radius “r” of the castellations 5. As a result, even if the displacement of the cover 3 with respect to the ceramic base 2 occurs in vertical direction, horizontal direction or oblique direction in plan view during sealing, this avoids the risk that the castellations 5 are covered with the cover 3.

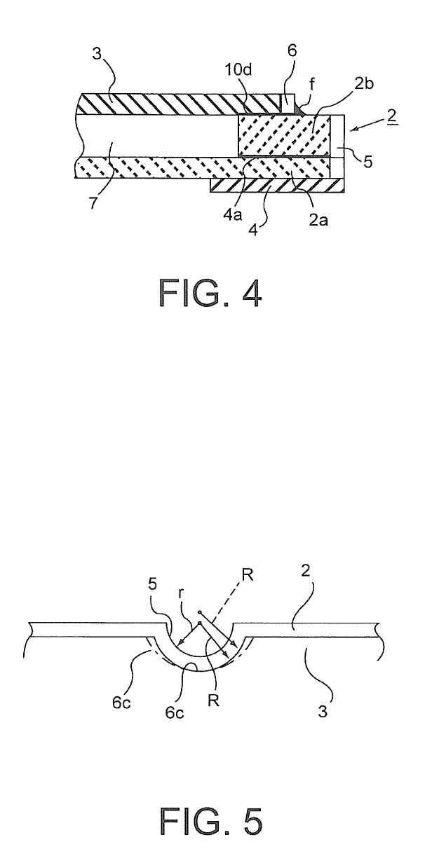

Here, in any of the above embodiments, as illustrated in FIG. 4, the cover 3, which has a notch 6 on the upper surface of the ceramic base 2 having the space portion 7, is firmly maintained and secured by the low melting point glass 10d and the fillet “f”. A wiring 4a, which electrically connects the end face electrodes 4 to internal electrodes, is formed via the castellation 5 between the lower surface of a ceramic substrate 2b of the ceramic base 2 and the upper surface of a ceramic substrate 2a of the ceramic base 2.

Further, as another embodiment of this disclosure, as illustrated in FIG. 5, even a crystal unit, which has the castellation 5 not at the four corners of the ceramic base 2 but on the long or short side surface of the ceramic base 2, can ensure the same objective as described above by arranging the notches 6c, which have a radius “R” larger than a radius “r” of the castellation 5, so as to be concentrically arranged with the radius “r” or displacing the centers of radiuses as shown by the chain line. In particular, when the radius of the notches 6c are formed so as to displace the centers of radiuses as shown by the chain line, thus extremely facilitating the visual recognition of the soldering portion.

In addition, the R parts may be conventionally formed at the four corners of the cover 3, and the outside dimension of the cover 3 may be formed to be larger than the inside dimension of the cavity 7 formed on the ceramic base 2, thus configuring the castellation 5 not to be covered with the R parts of the cover 3 during sealing.

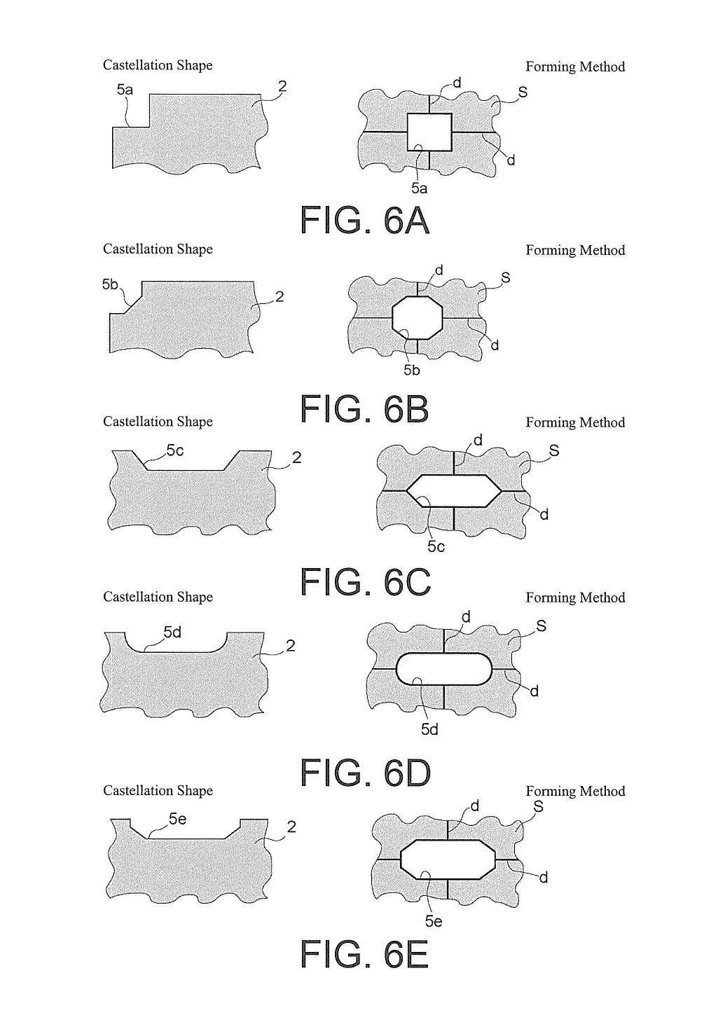

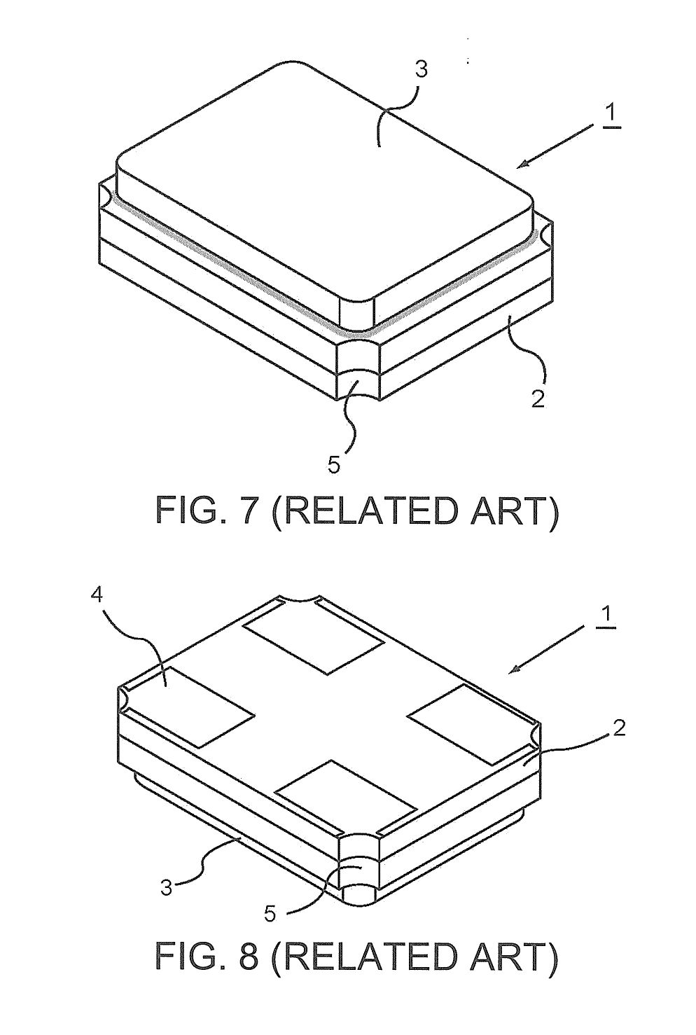

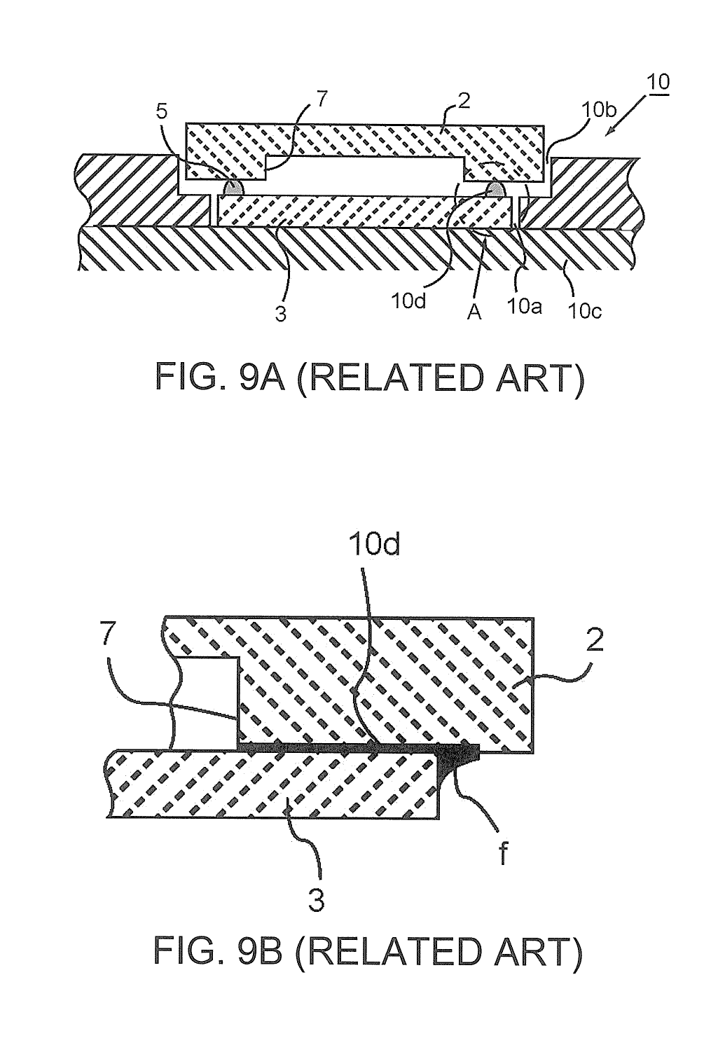

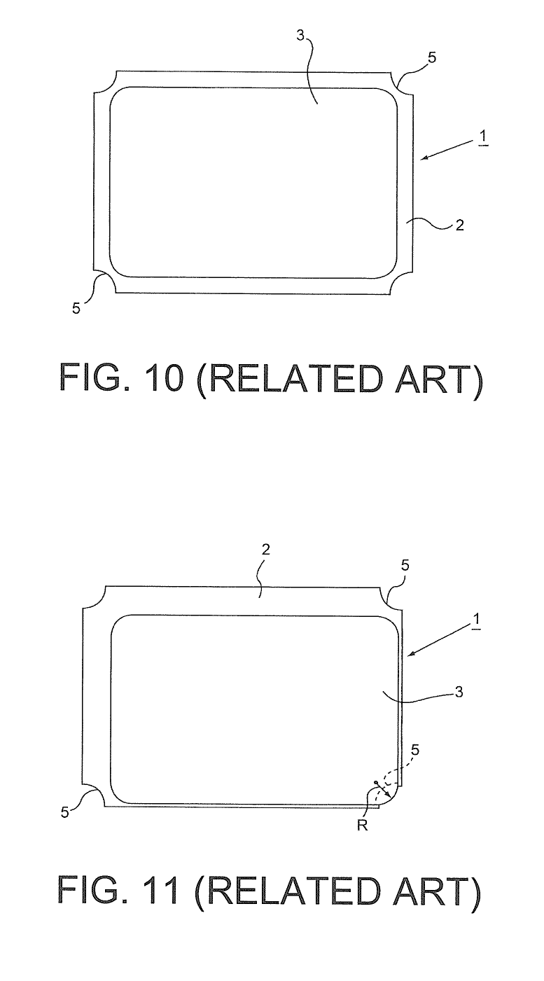

Further, as yet another embodiment of this disclosure, as illustrated in FIG. 6A, FIG. 6B, FIG. 6C, FIG. 6D, and FIG. 6E, modifications as the castellations 5a to 5e may be employed on the ceramic base 2.

Namely, as enlarged and illustrated in FIG. 6A, a rectangular castellation 5a may be formed at each of the four corners of the ceramic base 2, as illustrated in FIG. 6B, a castellation 5b with a shape obtained by equally dividing an octagon into four may be formed at each of the four corners of the ceramic base 2, as illustrated in FIG. 6C, a castellation 5c with a shape obtained by equally dividing a hexagon into two may be formed at the short side or the long side of the ceramic base 2, as illustrated in FIG. 6D, a castellation 5d with a shape obtained by equally dividing an ellipse into two may be formed at the short side or the long side of the ceramic base 2, and as illustrated in FIG. 6E, a castellation 5e with a shape obtained by equally dividing an elongated octagon into two may be formed at the short side or the long side of the ceramic base 2.

Here, the outside dimensions and the shapes of the notches 6, which are formed at the cover 3 having the castellations 5a to 5e with these different shapes in plan view, are needed to have the same dimensions/shapes as them or larger than them corresponding to the respective outside dimensions and the shapes of the castellations 5a to 5e.

Namely, the notch 6 of the castellation 5a illustrated in FIG. 6A is formed into the rectangular shape in plan view and is formed at each of the four corners of the cover 3. The notch 6 of the castellation 5b illustrated in FIG. 6B is formed into the shape obtained by equally dividing the octagon into four in plan view and is formed at each of the four corners of the cover 3. The notch 6 of the castellation 5c illustrated in FIG. 6C is formed into the shape obtained by equally dividing the hexagon into two in plan view and is formed on the short side surface or the long side surface of the cover 3. The notch 6 of the castellation 5d illustrated in FIG. 6D is formed into the shape obtained by equally dividing the ellipse into two in plan view and is formed on the short side surface or the long side surface of the cover 3. The notch 6 of the castellation 5e illustrated in FIG. 6E is formed into the shape obtained by equally dividing the elongated octagon into two in plan view and is formed on the short side surface or the long side surface of the cover 3.

However, unless the castellation 5a to 5e are covered with the cover 3 during sealing when viewed from the upper surface, any outside dimensions/shape may be employed.

As illustrated in the right hand margin of FIG. 6A, FIG. 6B, FIG. 6C, FIG. 6D, and FIG. 6E, the castellations 5a to 5e, which have the different outside dimensions/shapes, are formed as follows. Ceramic green sheet “S”, which is to be base materials of the plurality of bases 2, includes portions that become the four corners of the base and the short side surface or the long side surface of the base. These portions are formed by punching into the rectangular shape, the octagon shape, the hexagon shape, the ellipse shape, or the elongated octagon shape, and then by dividing into the pieces along each dicing line “d”.

Here, when each of the castellations 5 illustrated in FIG. 1A and FIG. 1B has a quarter circle shape in plan view, after the rectangular shape illustrated in FIG. 6A is replaced by a circular shape to be punched, it is formed by dividing into the pieces of the ceramic base 2, for example.

In the container for electronic component according to this disclosure, the notch may have a quarter circle shape in plan view and may be disposed at each of four corners of the cover.

In the container for electronic component according to this disclosure, the notch may have a chamfered surface shape or C shape in plan view and may be disposed at each of four corners of the cover.

In the container for electronic component according to the disclosure, the notch may have a quarter circle shape in plan view and may be disposed on the short side surface or the long side surface of the cover.

In the container for electronic component according to the disclosure, the notch may have a rectangular shape in plan view and may be disposed at each of four corners of the cover.

In the container for electronic component according to the disclosure, the notch may have a shape obtained by equally dividing an octagon into four in plan view and may be disposed at each of four corners of the cover.

In the container for electronic component according to the disclosure, the notch may have a shape obtained by equally dividing a hexagon into two and may be disposed at the short side or the long side of the cover.

In the container for electronic component according to the disclosure, the notch may have a shape obtained by equally dividing an ellipse into two and may be disposed at the short side or the long side of the cover.

In the container for electronic component according to the disclosure, the notch may have a shape obtained by equally dividing a elongated octagon into two and may be disposed at the short side or the long side of the cover.

In the container for electronic component according to the disclosure, the electronic component may include a crystal unit.

In the container for electronic component according to the disclosure, the electronic component may include a crystal oscillator.

With the container for electronic component of this disclosure, even if the displacement of the cover with respect to the base occurs in vertical direction, horizontal direction, or oblique direction in plan view to be sealed, the outside dimension of the notch formed on the cover is formed to be larger than a radial dimension of the castellation formed on the base. Therefore, the castellation is covered with the four corners of the cover after sealing. As a result, the image of the soldering portion can be correctly inspected from above the cover using the X-ray image inspection device.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A container for electronic component, comprising:
a base, having a side surface and an upper surface, a depressed castellation in plan view being disposed on the side surface; and
a cover that seals the upper surface airtight, wherein
the cover has an outside dimension smaller than an outside dimension of the base, and
the cover has a notch with a radial dimension larger than a depressed radial dimension of the castellation.

2. The container for electronic component according to claim 1, wherein
the notch has a quarter circle shape in plan view and is disposed at each of four corners of the cover.

3. The container for electronic component according to claim 1, wherein
the notch has a chamfered surface shape in plan view and is disposed at each of four corners of the cover.

4. The container for electronic component according to claim 1, wherein
the notch has a quarter circle shape in plan view and is disposed on the short side surface or the long side surface of the cover.

5. The container for electronic component according to claim 1, wherein
the notch has a rectangular shape in plan view and is disposed at each of four corners of the cover.

6. The container for electronic component according to claim 1, wherein
the notch has a shape obtained by equally dividing an octagon into four in plan view and is disposed at each of four corners of the cover.

7. The container for electronic component according to claim 1, wherein
the notch has a shape obtained by equally dividing a hexagon into two and is disposed at the short side or the long side of the cover.

8. The container for electronic component according to claim 1, wherein
the notch has a shape obtained by equally dividing an ellipse into two and is disposed at the short side or the long side of the cover.

9. The container for electronic component according to claim 1, wherein
the notch has a shape obtained by equally dividing an elongated octagon into two and is disposed at the short side or the long side of the cover.

10. The container for electronic component according to claim 1, wherein
the electronic component includes a crystal unit.

11. The container for electronic component according to claim 1, wherein
the electronic component includes a crystal oscillator.

12. An electronic component, comprising:
the container for electronic component according to claim 1.
